(19) United States
(12) Patent Application Publication
(10) Pub. No.: US 2026/0132325 A1
(43) Pub. Date: May 14, 2026

(54) THERMALLY CONDUCTIVE SILICONE COMPOSITION

(71) Applicant: DOW SILICONES CORPORATION, Midland, MI (US)

(72) Inventors: Yan HUANG, Shanghai (CN); Dorab BHAGWAGAR, Auburn, MI (US); Zhongwei CAO, Shanghai (CN); Kainan ZHANG, Shanghai (CN)

(21) Appl. No.: 19/119,621

(22) PCT Filed: Oct. 10, 2022
(86) PCT No.: PCT/CN2022/124318

§ 371 Date: Apr. 9, 2025

(51) Int. Cl. C09K 5/14; C04B 18/14; C04B 24/32; C04B 24/42; C04B 26/32

(52) U.S. Cl. CPC C09K 5/14; C04B 18/146; C04B 24/32; C04B 24/42; C04B 26/32; C04B 2201/32

(57) ABSTRACT

A thermally conductive silicone composition comprises: (A) an organopolysiloxane having at least one alkenyl group with 2 to 12 carbon atoms per molecule and having a viscosity at 25° C. of from 10 to 10,000 mPa·s; (B) a hydrophobic fumed silica; (C) at least one thermally conductive filler; and (D) at least one polyether selected from a group consisting of (D₁) a polytetramethylene ether glycol. (D₂) an alcohol initiated ethylene oxide and propylene oxide copolymer, and (D₃) a polyether-modified organopolysiloxane. The composition exhibits good shape-holding property and high thermal conductivity despite good handleability and dispensability.

### TECHNICAL FIELD

The present invention relates to a thermally conductive silicone composition exhibiting good shape-holding property and high thermal conductivity despite good handleability and dispensability.

### BACKGROUND ART

Thermally conductive silicone compositions are widely employed in various industries due to their unique properties, which include excellent electrical insulation and excellent thermal stability, and are therefore used as thermally conductive silicone greases, thermally conductive silicone gel compositions, thermally conductive silicone rubber compositions, or the like in a variety of applications, such as encapsulants or potting materials in electric/electronic devices where higher temperature may be needed. In a specific application, a thixotropic property of the thermally conductive silicone composition is needed to make its shape kept after dispensing it. It is well-known that the thixotropic property of the silicone composition is generally obtained by adding fine filler such as hydrophobic fumed silica, or some kinds of organic liquid compounds having polar groups, such as silanol groups, epoxy groups, amine groups, or polyether groups.

For example, Patent Document 1 discloses a silicone composition for preparing a cured silicone product, the composition comprising: an organopolysiloxane having on average at least two alkenyl groups per molecule, an organopolysiloxane having on average at least two silicon-bonded hydrogen atoms per molecule, an alumina filler, a polyether, and a hydrosilylation reaction catalyst.

Patent Document 2 discloses a thermally conductive silicone composition comprising: an organopolysiloxane having a viscosity of at least 500 mPa·s at 25° C., a thermally conductive filler; a fine silica powder, an organopolysiloxane represented by the specific general formula and having a viscosity of less than 500 mPa·s at 25° C., and a silane compound of the specific general formula.

Patent Document 3 discloses a heat-curable, heat-conductive silicone grease composition comprising: an organopolysiloxane having a viscosity of 100 to 100,000 mPa·s at 25° C. and having at least one alkenyl group per molecule, an organopolysiloxane having the specific general formula, an organopolysiloxane having at least two silicon-bonded hydrogen atoms per molecule, a catalyst selected from the group consisting of platinum and platinum compounds, a heat-conductive filler having a thermal conductivity of at least 10 W/m·° C., and finely divided silica.

Patent Document 4 discloses a normal temperature-storable, addition one-part heat-curable, heat-conductive silicone grease composition comprising: an organopolysiloxane having a viscosity of 50 to 100,000 mPa·s at 25° C. and having at least one alkenyl group per molecule, a liquid organopolysiloxane having a viscosity of up to 100 mPa·s at 25° C., having 2 to 10 Si—H groups per molecule, having at least one alkoxy and/or epoxy group bonded to a silicon atom through an alkylene group, the polysiloxane having a degree of polymerization of up to 15 and a cyclic structure-containing skeleton, a photoactive platinum complex curing catalyst, a heat-conductive filler having a thermal conductivity of at least 10 W/m·° C., an organopolysiloxane having the specific general formula, and a finely divided silica.

Patent Document 5 discloses a thermally conductive organopolysiloxane composition comprising: a thermally conductive filler, a siloxane compound represented by the specific general formula, an alkoxysilane compound represented by the specific general formula, an organopolysiloxane having one or more aliphatic unsaturated groups per molecule, an organopolysiloxane having two or more silicon atom-bonded hydrogen atoms per molecule, a platinum-based catalyst, and optionally, a fumed silica chemically treated with a silazane compound.

However, if for improving handleability and dispensability of such thermally conductive silicone compositions their viscosity is lowered, then after the coated surface assumes vertical position, the coating begins to slip-off.

### PRIOR ART DOCUMENTS

### Patent Documents

Patent Document 1: U.S. Pat. No. 6,448,329 A
Patent Document 2: U.S. Patent Application Publication No. 2011/0188213 A1
Patent Document 3: U.S. Patent Application Publication No. 2015/0148273 A1
Patent Document 4: U.S. Patent Application Publication No. 2019/0085167 A1
Patent Document 5: U.S. Patent Application Publication No. 2020/0140736 A1

### SUMMARY OF INVENTION

### Technical Problem

It is an object of the present invention to provide a thermally conductive silicone composition which possesses excellent handleability and dispensability at low viscosity and which, after application onto surfaces, is not slumped with time and is not subject to slipping-off even when this surface assumes a vertically position.

### Solution to Problem

The thermally conductive silicone composition of the present invention comprises:
(A) an organopolysiloxane having at least one alkenyl group with 2 to 12 carbon atoms per molecule and having a viscosity at 25° C. of from 10 to 10,000 mPa·s;
(B) a hydrophobic fumed silica;
(C) at least one thermally conductive filler; and
(D) at least one polyether selected from a group consisting of (D₁) a polytetramethylene ether glycol, (D₂) an alcohol initiated ethylene oxide and propylene oxide copolymer, and (D₃) a polyether-modified organopolysiloxane,
wherein a content of component (A) is in a range of from 0.5 to 5 mass %, a content of component (B) is in a range of from 0.01 to 0.5 mass %, a content of component (C) is at least 90 mass %, and a content of component (D) is in a range of from 0.05 to 5 mass %, each relative to a total amount of the composition.

In various embodiments, component (D₁) is typically a polytetramethylene ether glycol represented by the following general formula:

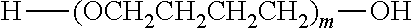

wherein m is an adequate number to give the polytetramethylene ether glycol a molecular weight a number average molecular weight (Mn) as measured by the gel permeation chromatography method of from 300 to 3,000.

In various embodiments, component (D₂) is typically an alcohol initiated ethylene oxide and propylene oxide copolymer comprising from 50 mass % to 99 mass % of propylene oxide units in the copolymer.

In various embodiments, component (D₃) is typically a polyether-modified organopolysiloxane selected from a polyether-grafted organopolysiloxane or a block copolymer of a polyether and an organopolysiloxane.

In various embodiments, the thermally conductive silicone composition may further comprise: (E) an organopolysiloxane having at least two silicon bonded hydrogen atoms per molecule, in an amount such that silicon atom-bonded hydrogen atoms in component (E) are 0.1 to 5 mol per 1 mol of the alkenyl groups in component (A); and (F) a hydrosilylation reaction catalyst in a sufficient amount to promote curing of the composition.

In various embodiments, the thermally conductive silicone composition may further comprise: (G) a hydrosilylation reaction inhibitor, in an amount sufficient to control cure speed of the composition.

In various embodiments, the thermally conductive silicone composition may further comprise: (H) a filler treating agent, in an amount sufficient to treat component (C).

In various embodiments, the thermally conductive silicone composition may further comprise: (I) a pigment, in an amount sufficient to preserve desired physical properties to the composition.

### Effects of Invention

The thermally conductive silicone composition of the present invention exhibits good shape-holding property and high thermal conductivity despite good handleability and dispensability.

### BRIEF DESCRIPTION OF DRAWINGS

FIG. 1 is a schematic photo for a long tailing observation test.

FIG. 2 is a schematic drawing to obtain each an aspect ratio (AR) at initial stage and after putting for 24 hours.

FIG. 3 is a schematic photo for an anti-slumping test.

FIG. 4 is a schematic photo for a vertical holding test.

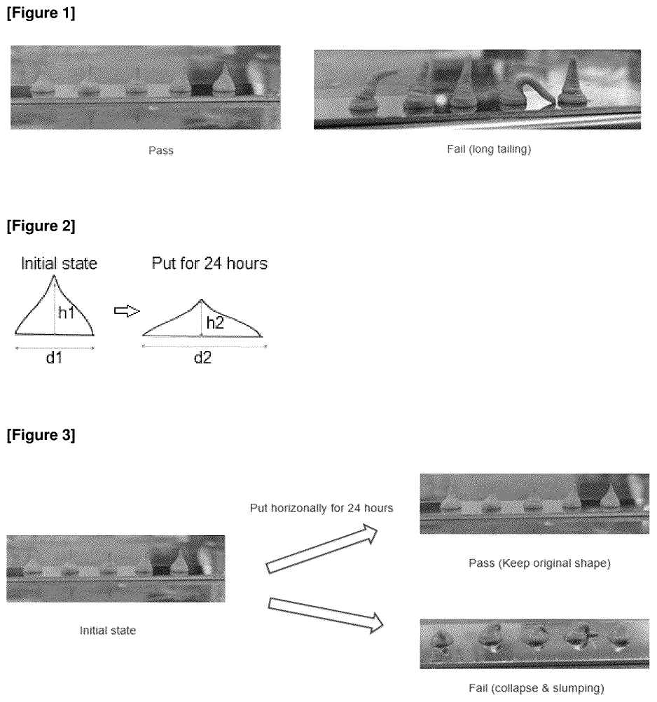

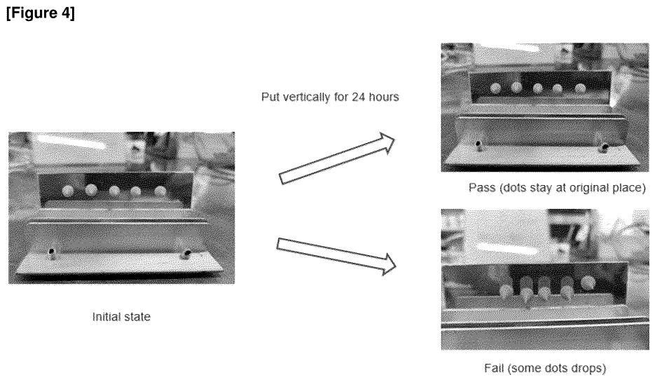

### DEFINITIONS

The terms “comprising” or “comprise” are used herein in their broadest sense to mean and encompass the notions of “including,” “include,” “consist (ing) essentially of,” and “consist(ing) of. The use of “for example,” “e.g.,” “such as,” and “including” to list illustrative examples does not limit to only the listed examples. Thus, “for example” or “such as” means “for example, but not limited to” or “such as, but not limited to” and encompasses other similar or equivalent examples. The term “about” as used herein serves to reasonably encompass or describe minor variations in numerical values measured by instrumental analysis or as a result of sample handling. Such minor variations may be in the order of ±0-25, ±0-10, ±0-5, or ±0-2.5, % of the numerical values. Further, the term “about” applies to both numerical values when associated with a range of values. Moreover, the term “about” may apply to numerical values even when not explicitly stated.

It is to be understood that the appended claims are not limited to express and particular compounds, compositions, or methods described in the detailed description, which may vary between particular embodiments which fall within the scope of the appended claims. With respect to any Markush groups relied upon herein for describing particular features or aspects of various embodiments, it is to be appreciated that different, special, and/or unexpected results may be obtained from each member of the respective Markush group independent from all other Markush members. Each member of a Markush group may be relied upon individually and or in combination and provides adequate support for specific embodiments within the scope of the appended claims.

It is also to be understood that any ranges and subranges relied upon in describing various embodiments of the present invention independently and collectively fall within the scope of the appended claims, and are understood to describe and contemplate all ranges including whole and/or fractional values therein, even if such values are not expressly written herein. One of skill in the art readily recognizes that the enumerated ranges and subranges sufficiently describe and enable various embodiments of the present invention, and such ranges and subranges may be further delineated into relevant halves, thirds, quarters, fifths, and so on. As just one example, a range “of from 0.1 to 0.9” may be further delineated into a lower third, i.e., from 0.1 to 0.3, a middle third, i.e., from 0.4 to 0.6, and an upper third, i.e., from 0.7 to 0.9, which individually and collectively are within the scope of the appended claims, and may be relied upon individually and/or collectively and provide adequate support for specific embodiments within the scope of the appended claims. In addition, with respect to the language which defines or modifies a range, such as “at least,” “greater than,” “less than,” “no more than,” and the like, it is to be understood that such language includes subranges and/or an upper or lower limit. As another example, a range of “at least 10” inherently includes a subrange of from at least 10 to 35, a subrange of from at least 10 to 25, a subrange of from 25 to 35, and so on, and each subrange may be relied upon individually and/or collectively and provides adequate support for specific embodiments within the scope of the appended claims. Finally, an individual number within a disclosed range may be relied upon and provides adequate support for specific embodiments within the scope of the appended claims. For example, a range “of from 1 to 9” includes various individual integers, such as 3, as well as individual numbers including a decimal point (or fraction), such as 4.1, which may be relied upon and provide adequate support for specific embodiments within the scope of the appended claims.

### DETAILED DESCRIPTION OF THE INVENTION

The thermally conductive silicone composition of the present invention will be explained in detail.

Component (A) is a primary component in the composition and is an organopolysiloxane having at least one alkenyl group with 2 to 12 carbon atoms per molecule. Examples of the alkenyl groups include vinyl groups, allyl groups, butenyl groups, pentenyl groups, hexenyl groups, heptenyl groups, octenyl groups, nonenyl groups, decenyl groups, undecenyl groups, and dodecenyl groups, among which vinyl groups are preferable. In addition, examples of groups bonding to silicon atoms other than the alkenyl groups in component (A) include alkyl groups with 1 to 12 carbon atoms such as methyl groups, ethyl groups, propyl groups, isopropyl groups, butyl groups, isobutyl groups, tert-butyl groups, pentyl groups, neopentyl groups, hexyl groups, cyclohexyl groups, heptyl groups, octyl groups, nonyl groups, decyl groups, undecyl groups, and dodecyl groups; aryl groups with 6 to 12 carbon atoms such as phenyl groups, tolyl groups, xylyl groups, and naphthyl groups; aralkyl groups with 7 to 12 carbon atoms such as benzyl groups, phenethyl groups, and phenylpropyl groups; and groups in which some or all of the hydrogen atoms of these groups are substituted with halogen atoms such as fluorine atoms, chlorine atoms, or bromine atoms. Furthermore, the silicon atoms in component (A) may have small amounts of hydroxyl groups or alkoxy groups such as methoxy groups or ethoxy groups within a range that does not impair the object of the present invention. However, the organopolysiloxane for component (A) does not have a polyether group in a molecule.

Examples of molecular structure of component (A) include a straight-chain structure, a partially branched straight-chain structure, a branched-chain structure, a cyclic structure, and a three-dimensional reticular structure. Component (A) may be one type of organopolysiloxane having these molecular structures or may be a mixture of two or more types of organopolysiloxanes having these molecular structures.

Examples of component (A) include a dimethylpolysiloxane capped at both molecular terminals with dimethylvinylsiloxy groups, a copolymer of dimethylsiloxane and methylvinylsiloxane capped at both molecular terminals with trimethylsiloxy groups, a copolymer of dimethylsiloxane and methylvinylsiloxane capped at both molecular terminals with dimethylvinylsiloxy groups, a copolymer of dimethylsiloxane, methylphenylsiloxane and methylvinylsiloxane capped at both molecular terminals with trimethylsiloxy groups, a copolymer of dimethylsiloxane and methylvinylsiloxane capped at both molecular terminals with silanol groups, an organopolysiloxane consisting of a siloxane unit represented by the formula: (CH₃)₃SiO_{1/2}, a siloxane unit represented by the formula: (CH₃)₂(CH₂═CH)SiO_{1/2}, a siloxane unit represented by the formula CH₃SiO_{3/2}, and a siloxane unit represented by the formula: (CH₃)₂SiO_{2/2}; and combinations of two or more thereof.

Additionally, a viscosity at 25° C. of component (A) is in a range of from 10 to 10,000 mPa·s, preferably in a range from 10 to 5,000 mPa·s, alternatively in a range from 10 to 3,000 mPa·s, or alternatively in a range from 50 to 2,000 mPa·s. This is because when it is greater than or equal to the lower limit of the aforementioned range, mechanical properties of a cured product of the composition is improved, and when it is less than or equal to the upper limit of the aforementioned range, handling of the composition is improved. Note that in the present specification, viscosity at 25° C. is the value measured using a rheometer according to ASTM D 1084.

A content of component (A) is in a range of from 0.5 to 5 mass % relative to a total amount of the composition. This is because when the content of component (A) is greater than or equal to the lower limit of the aforementioned range, handleability of the composition is improved, and when the content of component (A) is less than or equal to the upper limit of the aforementioned range, thermal conductive properties of the composition is improved.

Component (B) is a hydrophobic fumed silica, preferably a hydrophobic fumed silica with a BET specific surface area of from 100 to 400 m²/g, alternatively of from 150 to 400 m²/g, or alternatively of from 200 to 400 m²/g. This is because a thixotropic property of the composition is improved when the BET specific surface area of the fumed silica is in the range above.

A content of component (B) is in an amount of from 0.01 to about 0.5 mass %, preferably in an amount of from 0.01 to about 0.1 mass % relative to a total weigh of the composition. This is because when it is greater than or equal to the lower limit of the aforementioned range, the thixotropic property of the composition is improved, and when it is less than or equal to the upper limit of the aforementioned range, handleability and dispensability of the composition is improved.

Component (C) is at least one thermally conductive filler. For instance, component (C) can be any one or any combination of more than one thermally conductive filler selected from metals, alloys, nonmetals, metal oxides, metal hydrates or ceramics. Exemplary metals include but are not limited to aluminum, copper, silver, zinc, nickel, tin, indium, and lead. Exemplary nonmetals include but are not limited to carbon, graphite, diamond, carbon nanotubes, carbon fibers, graphene, silicon carbide and silicon nitride. Exemplary metal oxides, metal hydroxides and ceramics include but are not limited to alumina, aluminum hydroxide, aluminum nitride, boron nitride, zinc oxide, beryllium oxide, magnesium oxide and tin oxide. Desirably, component (C) is any one or any combination of more than one selected from a group consisting of alumina, aluminum, zinc oxide, boron nitride, aluminum nitride, and aluminum oxide trihydrate.

Component (C) is preferably a thermally conductive filler having an average particle size of from 0.1 μm to 50 μm. Even more desirably, component (C) is any one or any combination or more than one filler selected from aluminum oxide particles having an average size of less than 5 μm, aluminum oxide particles having an average particle size of 5 μm or more, aluminum hydroxide particles having an average size of less than 5 μm, aluminum hydroxide particles having an average particle size of 5 μm or more. Determine average particle size for filler particles as the median particle size (D50) using laser diffraction particle size analyzers (CILAS920 Particle Size Analyzer or Beckman Coulter LS 13 320 SW) according to an operation software.

A content of component (C) is at least 90 mass %, alternatively in a range of from 90 to 95 mass %, relative to a total amount of the composition. This is because when it is equal to or more than the lower limit of the aforementioned range, thermal conductive properties of the composition are good.

Component (D) is a polyether to provide the composition with excellent anti-slumping and vertical holding performance. Component (C) is at least one polyether selected from a group consisting of (D₁) a polytetramethylene ether glycol (hereinafter “PTMEG,” (D₂) an alcohol initiated ethylene oxide and propylene oxide copolymer (hereinafter “alcohol initiated EO/PO copolymer,” and (D₃) a polyether-modified organopolysiloxane not having an alkenyl group.

Component (D₁) is typically a polytetramethylene ether glycol represented by the following general formula:

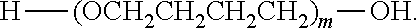

In the formula, m is an adequate number to give the PTMEG a molecular weight as described below. Specifically, m is preferably an integer satisfying: 5≤m≤50, alternatively an integer satisfying: 5≤m≤30, or alternatively an integer satisfying: 5≤m≤20.

While the molecular weight of such PTMEG is not limited, a number average molecular weight (Mn) as measured by the gel permeation chromatography method is preferably within a range of 300 to 3,000, or within a range of 300 to 2,500. This is because, if it is above the lower limit of the aforementioned range, the dynamic physical properties of the cured product obtained will be good; however, on the other hand, if it is below the upper limit of the aforementioned range, the applicability of the composition will be enhanced.

Component (D₁) is commercially available as PTMEG 1000, PTMEG 1400, and PTMEG 2000 from Aladdin.

Component (D₂) is typically an alcohol initiated EO/PO copolymer represented by the general formula:

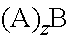

where A represents HO—(C₃H₆—O)ₓ—(C₂H₄—O)_{y}—, wherein x is from 8 to 40, y is from 1 to 20; z is from 1 to 12; and B is hydrogen or a monovalent, bivalent, or multivalent hydrocarbon group having from 3 to 18 carbon atoms.

The sequence of the ethylene oxide units (—C₂H₄—O—) and propylene oxide units (—C₃H₆—O—) in segment A may be random or may be oriented in block configurations of any kind such as a single block of ethylene oxide units and a single block of propylene oxide units.

In the formula above, x and y are the average number of propylene oxide units and ethylene oxide units, respectively. The value of x can be from 8 to 40, from 10 to 35, from 15 to 30, or from 20 to 28. The value of y can be from 1 to 20, from 1 to 18, or from 1 to 16.

In the formula above, z can be from 1 to 12, from 2 to 10, from 3 to 8, or from 4 to 6.

In the formula above, the value of (x+y+z) is sufficient to give the alcohol initiated EO/PO copolymer a molecular weight as described below.

In the formula above, B may have from 3 to 18 carbon atoms, 3 or 12 carbon atoms, from 3 to 10 carbon atoms, from 3 to 8 carbon atoms, or from 4 to 6 carbon atoms. When B is a monovalent or bivalent hydrocarbon group, the alcohol initiated EO/PO copolymer has a linear structure. When B is a multivalent (e.g., trivalent or higher valent) hydrocarbon group, the alcohol initiated EO/PO copolymer has a branched structure. B can be a group derived from sorbitol or a group derived from glycerol.

The alcohol initiated EO/PO copolymer can be prepared from an alcohol initiator having 3 carbon atoms or more, 4 carbon atoms or more, 5 carbon atoms or more, or even 6 carbon atoms or more, and at the same time typically 18 carbon atoms or less, 12 carbon atoms or less, 10 carbon atoms or less, 8 carbon atoms or less, or even 6 carbon atoms or less. The alcohol initiator can be linear or branched alcohol and preferably, a branched alcohol. The alcohol initiator can be a mono, diol, triol, tetrol, pentol or hexol. Preferably, the alcohol initiator is a hexol. Preferably, the alcohol initiator for preparing the EO/PO copolymer is sorbitol, glycerol, or mixtures thereof. Methods and conditions used for the preparation of the alcohol initiated EO/PO copolymer are known to those skilled in the art, for example, at temperatures ranging from 20 to 180° C. or from 100 to 160° C. Preparation of the alcohol initiated EO/PO copolymer may be found in, for example, J. Herzberger et al., “Polymerization of ethylene oxide, propylene oxide, and other alkylene oxides: synthesis, novel polymer architectures, and bioconjugation,” Chemical Reviews, Volume 116, Issue No. 4, pages 2170-2243 (2016).

The alcohol initiated EO/PO copolymer may comprise, by weight based on the weight of the alcohol initiated EO/PO copolymer, the propylene oxide units (also as propylene oxide chains) in an amount of 50 mass % or more, 52 mass % or more, 55 mass % or more, 58 mass % or more, 60 mass % or more, 62 mass % or more, or even 65 mass % or more, at the same time, 99 mass % or less, 98 mass % or less, 97 mass % or less, 96 mass % or less, or even 95 mass % or less.

While the molecular weight of such component (D₂) is not limited, it is preferably greater than 2,000 g/mol, for example, 2,100 g/mol or more, 2,200 g/mol or more, 2,300 g/mol or more, 2,500 g/mol or more, 2,600 g/mol or more, 2,700 g/mol or more, 2,800 g/mol or more, 2,900 g/mol or more 3,000 g/mol or more, 3,200 g/mol or more, 3,500 g/mol or more, 3,800 g/mol or more, 4,000 g/mol or more, 4,500 g/mol or more, 5,000 g/mol or more, 5,500 g/mol or more, 6,000 g/mol or more, 6,500 g/mol or more, 7,000 g/mol or more, 7,500 g/mol or more, 8,000 g/mol or more, or even 9,000 g/mol or more, at the same time, 20,000 g/mol or less, 19,000 g/mol or less, 18,000 g/mol or less, 17,000 g/mol or less, 16,000 g/mol or less, 15,000 g/mol or less, or even 14,000 g/mol or less. Molecular weight herein refers to number average molecular weight (Mn) as measured by the gel permeation chromatography method and is calculated by (56100*f)/OHV, where f represents an average number of hydroxyl groups per molecule of the alcohol initiated EO/PO copolymer (also referred as “OH functionality”), and OHV represents hydroxyl value of the alcohol initiated EO/PO copolymer in the units of mg KOH/g as determined by ASTM D4274-2011. This is because, if it is above the lower limit of the aforementioned range, the dynamic physical properties of the cured product obtained will be good; however, on the other hand, if it is below the upper limit of the aforementioned range, the applicability of the composition will be enhanced.

The polyether-modified organopolysiloxane for component (D₃) is not limited and may be any organopolysiloxane including at least one polyether group. The polyether group of the polyether-modified organopolysiloxane may be pendent, terminal, or in both pendent and terminal locations. Component (D₃) is typically a polyether-modified organopolysiloxane selected from a polyether-grafted organopolysiloxane or a block copolymer of a polyether and an organopolysiloxane. For example, the polyether group may be part of the backbone of the polyether-modified organopolysiloxane. Alternatively or in addition, the backbone of the polyether-modified organopolysiloxane may include only siloxane (Si—O—Si) bonds, or may include divalent hydrocarbon linking groups, as well as other heteroatoms, such as O, N, and/or S. The polyether-modified organopolysiloxane may comprise any combination of M, D, T, and/or Q siloxy units. Typically, however, the polyether-modified organopolysiloxane is linear and does not include branching attributable to T and/or Q units.

Component (D₃) is commercially available from Sigma-Aldrich.

A content of component (D) is in a range of from 0.05 to 5 mass % relative to a total amount of the composition. This is because when it is greater than or equal to the lower limit of the aforementioned range, the anti-slumping property and vertical holding property of the composition is improved, and when it is less than or equal to the upper limit of the aforementioned range, the stability of the composition is improved.

Addition of a curing agent makes the composition curable. If the composition is to be cured with a hydrosilylation reaction, such a curing agent is composed of (E) an organopolysiloxane having at least two silicon bonded hydrogen atoms per molecule and (F) a hydrosilylation reaction catalyst.

Component (E) is a crosslinking agent for component (A) in the composition and is an organopolysiloxane having at least two silicon atom-bonded hydrogen atoms per molecule. Examples of groups bonding to silicon atoms other than hydrogen groups in component (E) include alkyl groups with 1 to 12 carbon atoms such as methyl groups, ethyl groups, propyl groups, isopropyl groups, butyl groups, isobutyl groups, tert-butyl groups, pentyl groups, neopentyl groups, hexyl groups, cyclohexyl groups, heptyl groups, octyl groups, nonyl groups, decyl groups, undecyl groups, and dodecyl groups; aryl groups with 6 to 20 carbon atoms such as phenyl groups, tolyl groups, xylyl groups, and naphthyl groups; aralkyl groups with 7 to 20 carbon atoms such as benzyl groups, phenethyl groups, and phenylpropyl groups; and groups in which some or all of the hydrogen atoms of these groups are substituted with halogen atoms such as fluorine atoms, chlorine atoms, or bromine atoms. Furthermore, the silicon atoms in component (E) may have small amounts of hydroxyl groups or alkoxy groups such as methoxy groups or ethoxy groups within a range that does not impair the object of the present invention. However, the organopolysiloxane for component (E) has neither a polyether group nor an alkenyl group in a molecule.

Examples of the molecular structure of component (E) include straight-chain, partially branched straight-chain, branched chain, cyclic, and three-dimensional reticular structures, and the molecular structure is preferably a straight-chain, partially branched straight-chain, branched chain, or three-dimensional reticular structure.

Examples of such component (E) include a methylhydrogenpolysiloxane capped at both molecular terminals with trimethylsiloxy groups, a copolymer of dimethylsiloxane and methylhydrogensiloxane capped at both molecular terminals with trimethylsiloxy groups, a dimethylpolysiloxane capped at both molecular terminals with dimethylhydrogensiloxy groups, a copolymer of dimethylsiloxane and methylhydrogensiloxane capped at both molecular terminals with dimethylhydrogensiloxy groups, a copolymer of methylhydrogensiloxane and diphenylsiloxane capped at both molecular terminals with trimethylsiloxy groups, a copolymer of methylhydrogensiloxane, diphenylsiloxane and dimethylsiloxane capped at both molecular terminals with trimethylsiloxy groups, a copolymer consisting of (CH₃)₂HSiO_{1/2} units and SiO_{4/2} units, copolymers consisting of (CH₃)₂HSiO_{1/2} units, SiO_{4/2} units, and (C₆H₅)SiO_{3/2} units, and mixtures of two or more types thereof.

A content of component (E) is in an amount to provide 0.5 to 5 moles, preferably 0.5 to 3 moles, alternatively 0.5 to 2 moles of silicon atom-bonded hydrogen atoms per 1 mole of alkenyl groups in component (A). This is because, when it is equal to or greater than the lower limit of the range described above, the composition is cured sufficiently. On the other hand, when it is equal to or less than the upper limit of the range described above, heat resistance of the cured product is enhanced.

Component (F) is a hydrosilylation catalyst to accelerate curing of the composition. Examples of component (F) include platinum group element catalysts and platinum group element compound catalysts, and specific examples include platinum-based catalysts, rhodium-based catalysts, palladium-based catalysts, and combinations of at least two types thereof. In particular, platinum-based catalysts are preferable in that the curing of the present composition can be dramatically accelerated. Examples of these platinum-based catalysts include finely powdered platinum; platinum black; chloroplatinic acid, alcohol-modified chloroplatinic acid; chloroplatinic acid/diolefin complexes; platinum/olefin complexes; platinum/carbonyl complexes such as platinum bis(acetoacetate), and platinum bis(acetylacetonate); chloroplatinic acid/alkenylsiloxane complexes such as chloroplatinic acid/divinyltetramethyl disiloxane complexes, and chloroplatinic acid/tetravinyl tetramethyl cyclotetrasiloxane complexes; platinum/alkenylsiloxane complexes such as platinum/divinyltetramethyl disiloxane complexes, and platinum/tetravinyl tetramethyl cyclotetrasiloxane complexes; complexes of chloroplatinic acid and acetylene alcohols; and mixtures of two or more types thereof. In particular, platinum-alkenylsiloxane complexes are preferable in that the curing of the composition can be accelerated.

Examples of the alkenylsiloxane used in the platinum-alkenylsiloxane complex include 1,3-divinyl-1,1,3,3-tetramethyldisiloxane, 1,3,5,7-tetramethyl-1,3,5,7-tetravinylcyclotetrasiloxane, alkenylsiloxane oligomers in which some of methyl groups of these alkenylsiloxanes are substituted with ethyl groups, phenyl groups, or the like, and alkenylsiloxane oligomers in which vinyl groups of these alkenylsiloxanes are substituted with allyl groups, hexenyl groups, or the like. In particular, 1,3-divinyl-1,1,3,3-tetramethyldisiloxane is preferable in that the stability of the platinum-alkenylsiloxane complex that is produced is good.

In order to improve the stability of the platinum-alkenylsiloxane complexes, it is preferable to dissolve these platinum-alkenylsiloxane complexes in an alkenylsiloxane oligomer such as 1,3-divinyl-1,1,3,3-tetramethyldisiloxane, 1,3-diallyl-1,1,3,3-tetramethyldisiloxane, 1,3-divinyl-1,3-dimethyl-1,3-diphenyldisiloxane, 1,3-divinyl-1,1,3,3-tetraphenyldisiloxane, or 1,3,5,7-tetramethyl-1,3,5,7-tetravinylcyclotetrasiloxane or an organosiloxane oligomer such as a dimethylsiloxane oligomer, and it is particularly preferable to dissolve the complexes in an alkenylsiloxane oligomer.

A content of component (F) is a catalytic amount to accelerate the curing of the composition, but it is preferably in an amount of from about 0.01 to about 1,000 ppm of the platinum group metal in this component in terms of mass units with respect to this composition. Specifically, the content is preferably an amount such that the content of platinum group metal in component (F) is in the range of from about 0.01 to about 500 ppm, alternatively in the range of from about 0.1 to about 100 ppm in terms of mass units with respect to the composition. This is because when it is equal to or greater than the lower limit of the range described above, curability of the composition is good, whereas when it is equal to or less than the upper limit of the range described above, coloration of the cured product is suppressed, cost of the composition is lowered and cure rate of the present composition can be controlled.

The composition may comprise (G) a hydrosilylation reaction inhibitor in order to prolong the usable time at ambient temperature and to improve storage stability. Examples of component (G) include acetylenic alcohols such as 1-ethynyl-cyclohexan-1-ol, 2-methyl-3-butyn-2-ol, 2-phenyl-3-butyn-2-ol, 2-ethynyl-isopropan-2-ol, 2-ethynyl-butan-2-ol, and 3,5-dimethyl-1-hexyn-3-ol; silylated acetylenic alcohols such as trimethyl (3,5-dimethyl-1-hexyn-3-oxy) silane, dimethyl bis(3-methyl-1-butyn-oxy) silane, methylvinyl bis(3-methyl-1-butyn-3-oxy) silane, and ((1,1-dimethyl-2-propynyl)oxy)trimethylsilane; unsaturated carboxylic esters such as diallyl maleate, dimethyl maleate, diethyl fumarate, diallyl fumarate, and bis(2-methoxy-1-methylethyl) maleate, mono-octylmaleate, mono-isooctylmaleate, mono-allyl maleate, mono-methyl maleate, mono-ethyl fumarate, mono-allyl fumarate, and 2-methoxy-1-methylethylmaleate; ene-yne compounds such as 2-isobutyl-1-buten-3-yne, 3,5-dimethyl-3-hexen-1-yne, 3-methyl-3-penten-1-yne, 3-methyl-3-hexen-1-yne, 1-ethynyl cyclohexene, 3-ethyl-3-buten-1-yne, and 3-phenyl-3-buten-1-yne; and mixtures of two or more types thereof.

A content of component (G) is not limited as long as it is sufficient amount to control a cure speed of the composition. However, it is preferably in an amount of from about 0.001 to 5 parts by mass, alternatively in an amount of from about 0.001 to about 2 parts by mass, or alternatively in an amount of from about 0.001 to about 1 part(s) by mass, relative to 100 parts by mass of component (A). This is because when it is equal to or greater than the lower limit of the range described above, handing of the composition is good, whereas when it is equal to or less than the upper limit of the range described above, curability of the composition at low temperatures is good.

Component (H) is at least one filler treating agent to assist dispersing of component (C) in component (A). Component (H) is not limited, but it is preferably a filler treating agent selected from
(H₁) an organosiloxane represented by the following general formula (1):

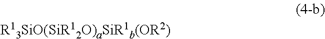

(H₂) an alkoxysilane represented by the following general formula (2):

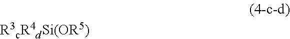

and a mixture of components (H₁) and (H₂).

In the formula (1), each R¹ is independently an alkyl group with 1 to 3 carbon atoms or an alkenyl group with 2 to 6 carbon atoms. Examples of alkyl groups for R¹ include methyl groups, ethyl groups, and propyl groups, among which methyl groups are preferable. Examples of alkenyl groups for R¹ include vinyl groups, allyl groups, butenyl groups, pentenyl groups, and hexenyl groups, among which vinyl groups are preferable.

In the formula (1), each R² is independently an alkyl group with 1 to 3 carbon atoms. Examples of alkyl groups for R⁴ include methyl groups, ethyl groups, and propyl groups, among which methyl groups are preferable.

In the formula (1), a is an integer of 5 to 150, alternatively an integer of 10 to 120.

In the formula (1), b is 0 or 1, and preferably 0.

Examples of component (H₁) include organosiloxanes represented by the following formulae:

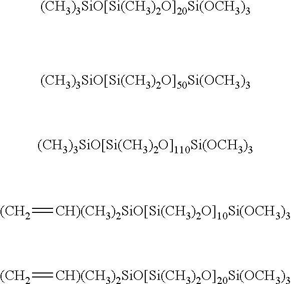

In the formula (2), each R³ is independently an alkyl group with 1 to 3 carbon atoms. Examples of alkyl groups for R³ include methyl groups, ethyl groups, and propyl groups, among which methyl groups are preferable.

In the formula (2), each R⁴ is independently an alkyl group with 6 to 12 carbon atoms. Examples of alkyl groups for R⁴ include hexyl groups, cyclohexyl groups, heptyl groups, octyl groups, nonyl groups, decyl groups, undecyl groups, and dodecyl groups, among which octyl groups and decyl groups are preferable.

In the formula (2), each R⁵ is independently an alkyl group with 1 to 3 carbon atoms. Examples of alkyl groups for R⁵ include methyl groups, ethyl groups, and propyl groups, among which methyl groups are preferable.

In the formula (2), c is 0 or 1, d is 0 or 1, provided that c+d is 1 or 2.

Examples of alkoxysilanes for component (H₂) include methyl trimethoxysilane, hexyl trimethoxysilane, heptyl trimethoxysilane, octyl triethoxysilane, decyl trimethoxysilane, dodecyl trimethoxysilane, dodecyl methyl dimethoxysilane, dodecyl triethoxysilane, tetradecyl trimethoxysilane, octadecyl trimethoxysilane, octadecyl methyl dimethoxysilane, octadecyl triethoxysilane, nonadecyl trimethoxysilane, or any combination of at least two thereof.

A content of component (H) is not limited as long as it is sufficient amount to treat component (C). However, it is preferably in a range of from 0.1 to 5 mass %, alternatively in a range of from 0.1 to 3 mass %, or alternatively in a range of from 0.5 to 3 mass %, of the composition. This is because when it is equal to or greater than the lower limit of the range described above, component (C) is sufficiently surface-treated to be load into the composition, whereas when it is equal to or less than the upper limit of the range described above, storage stability of the composition is good.

The present composition may further comprise (I) a pigment that has an effect of preserving the desired physical characteristic of a cured product of the composition, namely the appropriate softness and compliant nature. Examples of component (I) include iron oxide red, titanium white, carbon black, and phthalocyanine compound. Among these, the phthalocyanine compound is preferably. Examples of the phthalocyanine compounds include copper phthalocyanine, and chlorinated copper phthalocyanine. Phthalocyanine compounds are available commercially from Alfa-Aesar.

A content of component (I) is not limited as long as it is sufficient amount to preserve the desired physical properties. However, it is preferably in an amount such that in terms of mass units the pigment is in a range of 0.01 to 5 parts by mass, alternatively in a range of 0.05 to 5 parts by mass, or alternatively in a range of 0.05 to 1 parts by mass, relative to 100 parts by mass of component (A).

Furthermore, the addition of small quantities of supplementary components to the present composition is permissible. Such supplementary components are, for example, the various fillers other than thermally conductive filler and fumed silica filler, antioxidants, dyes, heat stabilizers, adhesion promoters, flame retardants, plasticizers, etc.

While the viscosity at 25° C. of the present composition is not limited, it is preferably 10,000 Pa's or less, within a range of 500 to 10,000 Pas, or within a range of 1,000 to 10,000 Pa·s. This is because, if the viscosity of the composition is above the lower limit of the aforementioned range, the mechanical properties of the cured product obtained will be good; however, if, on the other hand, the viscosity is below the upper limit of the aforementioned range, the handleability of the composition obtained will be enhanced and air is less likely to be entrained in the cured product.

The composition can be prepared by uniformly mixing components (A) to (D), and if necessary, any other components. When preparing the present composition, mixing can be performed at ordinary temperature using various types of stirrers or kneaders, and if necessary, mixing can be performed while heating. Furthermore, the order of combining the various components is not restricted, and mixing can be performed in any order. Moreover, the composition can be a one part composition in which all of the components are blended in the same container, or can be a two part composition which mixes during use in view of storage stability.

### EXAMPLES

The thermally conductive silicone composition of the present invention will be described in detail hereinafter using Examples and Comparative Examples. However, the present invention is not limited by the description of the below listed Examples. Viscosities were measured at 25° C. Furthermore, in the examples, measurements and evaluations were carried out as described below.

### <Thermal Conductivity>

Thermal conductivity (W/m·K) was measured by means of Thermal Interface Material (TIM) Tester manufactured by LONGWIN instrument in accordance with ASTM D 5470 “Standard Test Method for Thermal Transmission Properties of Thermally Conductive Electrical Insulation Materials.”

### <Dispensing Rate>

Loading thermally conductive silicone composition in 30 cc EFD plastic cartridge with no tip, and then dispensing the thermally conductive silicone composition under 90 psi (621 KPa), and record the weight of dispensed composition in one minute. Repeat the testing for 5 times and record the average value.

### <Long Tailing Observation>

After dispensing 5 pieces of small approximately 0.15 mL of sample dots, observe if there is a long tail at the end, and if the tail is not easy to break. Check if the material forms a tail when the dispensing syringe is raised. The sample dot has total height around 10 mm. If the total height of sample dot is larger than 1.2 mm, and the tail height is more than 5 mm, it will be recorded as fail.

### <Anti-Slumping Test>

Dispensing 5 pieces of small sample dots on Al plate, measured the height and bottom length of dots. Put the Al plate horizontally for 24 hours. Observe the dots shapes and measured the height and bottom length of dots to calculate the aspect ratio of the dispensed dot. Calculate the slumping tendency (ST) value which is the change in aspect ratio over 24 hrs time. If ST≤1.05, it can be marked as “no slumping”. If the value >1.05, it will be marked as “slumping.”

The aspect ratios (AR) of dispensed sample dot can be defined as (height/diameter) of the specimen

$$AR = h / d$$

The slumping tendency (ST) of dispensed sample dot can be defined as the ratio of initial AR of the specimen to the AR of the specimen after a certain time.

$$SR = AR 1 / AR 2 = ( h 1 * d 2 ) / ( d 1 * h 2 )$$

If ST>1, it indicates the sample has horizontal slumping tendency.

The higher ST value means the stronger slumping tendency.

### <Vertical Holding>

Dispensing 5 sample dots with 0.4 g and 1 g on Al plate, respectively. Put the Al plate vertically for 24 hours and observe if the sample dots stay at original place.

### <Viscosity and Thixotropic Index>

Viscosity at 25° C. was measured by using an ARES G2 rheometer with the following conditions: 25 mm diameter serrated parallel plates; 1 mm gap; Flow sweep mode; shear rate: 0.1 (1/s) and 1 (1/s) according to ASTM D 1084 “Standard Test Methods for Viscosity of Adhesive.” Thixotropic Index is given by the formula:

$$Thixotropic index = η ( 0.1 ) / η ( 1 )$$

wherein η(0.1) is the viscosity at lower shear rate: 0.1 (1/s) and η(1) is the viscosity at higher shear rate: 1 (1/s).

The following components were used to prepare the thermally conductive silicone compositions in Examples and Comparative Examples.

The following components were used as component (A).
V-P1: a dimethylpolysiloxane represented by the following formula:

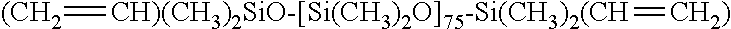

and having a viscosity of 78 mPa·s and a vinyl groups content of 1.25 mass %
V-P2: a dimethylpolysiloxane represented by the following formula:

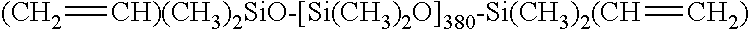

and having a viscosity of 2000 mPa·s and a vinyl groups content of 0.24 mass %

The following component was used as component (B).
Filler-1: a hydrophobic fumed silica with a BET specific surface between 175-225 m²/g (AEROSIL 200V from Evonik)

The following components were used as component (C).
Filler-2: Spherical Al₂O₃ with an average particle size of 90 μm (Available under the name DAW-90 from Denka Company Limited in Japan)
Filler-3: Roundish Al₂O₃ with an average particle size of 35 μm (Available under the name A-SF-60 from Chialco)
Filler-4: Irregular Al₂O₃ with an average particle size of 2 μm (Available under the name AZ2-75 from Nippon Steel & Sumikin Materials Co., Ltd.)
Filler-5: ZnO with an irregular particle size and an average particle size of 0.11-0.13 μm (Commercially available as Zoco 102 from Zochem)
Filler-6: Platelet shaped Boron Nitride filler with an average particle size along the platelet of ˜45 μm, platelet thickness between 5-10 μm (Commercially available as PolarTherm PT110 from Momentive Performance Materials)
Filler-7: Spherical AlN with average particle size of 80 μm (Commercially available as ANF S-80 ST204 from Maruwa Ceramic Co. Ltd. of Japan)
Filler-8: spherical Al₂O₃ with an average particle size of 2 μm (Available under the name ALUNABEADS™ CB-P02 from Showa Denko Company)

The following components were used as component (H).
TA 1: n-decyltrimethoxysilane (Available under the name SID2670.0 from Gelest)
TA 2: organopolysiloxane represented by the average formula:

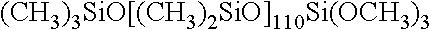

The following component was used as component (I).
Blue Pigment: Copper Phthalocyanine Powder (CuPc) CAS 147-14-8 (40% by weight) dispersed by 3-roll mill in Trimethyl terminated polydimethylsiloxane with a viscosity of 350 mPa·s (200Fluid) (60% by weight) Alfa-Aesar Catalogue No 43650-09 and DOWSIL™ 200 Fluid 350 cSt

The following component was used as component (G).
Inhibitor: methyl(tris(1,1-dimethyl-2-propynyloxy)) silane (Commercially available from Alfa Chemistry, 2200 Smithtown Avenue, Ronkonkoma, NY as ACM83817714)

The following components were used as component (D).
Additive-1: PTMEG Poly(tetramethylene ether glycol) with Mn=about 1000 to about 2000) (Commercially available as PTMEG 2000 from Aladdin)
Additive-2: EO-PO copolymer polyalkoxylate comprising ethylene oxide/propylene oxide bock copolymer, alcohol alkoxylate (propylene oxide=94 mass %) initiated by sorbitol. The copolymer has Mn of 9,600 g/mol, viscosity of 13,400 mPa·s at 25° C., with OHV of 30-36 mg KOH/g), OHV represents hydroxyl value of the alcohol alkoxylate determined by ASTM D4274-2011 (Commercially available from Dow as DOWFAX™ DF-162 Nonionic Surfactant)
Additive-3: a polyether-grafted organopolysiloxane obtained by hydrosilylation reacting a copolymer of dimethylsiloxane and methylhydrogensiloxane with a polyoxyethylene polyoxypropylene glycol monoacetate allyl ether (CAS 68037-64-9) (Available from Sigma-Aldrich)

The following component was used as component (E).
XL 1: a copolymer of dimethylsiloxane and methylhydrogensiloxane endcapped with trimethylsiloxy group at both molecular chain terminals and having a viscosity of 19 mPa·s, having 0.11 mole % of SiH, and represented by the following average formula:

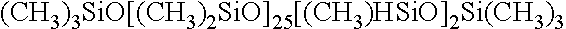

(Commercially available as HMS-071 from Gelest)

The following component was used as component (F).
Pt 1: platinum-divinyltetramethyldisiloxane complex (CAS 68478-92-2); 1.0% Pt in vinyl terminated PDMS (Available form Gelest)

### Examples IE1 to IE5 and Comparative Examples CE1 and CE2

The thermally conductive silicone compositions shown in Table 1 were prepared using 1 L Sigma-blade kneader mixer.

Load the specified amount of V-P1, V-P2, TA 1, TA2 and Pigment into the mixer and mix for 5 minutes at 20 revolutions per minute (RPM) under nitrogen flow at 0.4 cubic meters per hour. Add Filler-1 and Filler-5 while mixing and continue mixing for 10 minutes at 45 RPM under nitrogen purge. Add the Filler-8 and mix for 10 minutes at 45 RPM under nitrogen purge. Stop mixing and scrape material down from the walls of the mixing container and cover. Add Filler-6 and Filler-7 and mix for 10 minutes at 30 RPM under nitrogen purge. Stop mixing and scrape material down from the walls of the mixing container. Continue mixing at 30 RPM under vacuum and heat to 130° C. for 40 minutes. Cool to 40° C., stop mixing and release vacuum. Scrape material down from the container wall and mixer blade. Add Inhibitor, XL 1 and Additives 1-3, and mix for 15 minutes at 30 RPM under nitrogen purge then for 15 minutes. Cool to 25° C., adding Pt 1 into mixer, mix for 45 mins at 30 RPM under nitrogen purge. Continue mixing for 20 mins at 30 RPM with full vacuum. Stop mixing and release the vacuum to obtain the thermally conductive silicone compositions for CE or IE.

TABLE 1

| | | | Category | | | | | | |
|---|---|---|---|---|---|---|---|---|---|
| | | | Examples | | | | | Comparative Example | |
| Item | | | IE 1 | IE 2 | IE 3 | IE 4 | IE 5 | CE 1 | CE 2 |
| Thermally | (A) | V-P1 | 1.16 | 0.96 | 1.58 | 1.16 | 1.16 | 1.36 | 1.78 |
| Conductive | | V-P2 | 0.13 | 0.13 | 0.13 | 0.13 | 0.13 | 0.13 | 0.13 |
| silicone | (B) | Filler-1 | 0.05 | 0.05 | 0.05 | 0.05 | 0.05 | 0.05 | 0.05 |
| composition | (C) | Filler-2 | 0 | 0 | 0 | 0 | 0 | 0 | 0 |
| (parts | | Filler-3 | 0 | 0 | 0 | 0 | 0 | 0 | 0 |
| by mass) | | Filler-4 | 0 | 0 | 0 | 0 | 0 | 0 | 0 |
| | | Filler-5 | 16.92 | 16.92 | 16.92 | 16.92 | 16.92 | 16.92 | 16.92 |
| | | Filler-6 | 0.2 | 0.2 | 0.2 | 0.2 | 0.2 | 0.2 | 0.2 |
| | | Filler-7 | 48.39 | 48.39 | 48.39 | 48.39 | 48.39 | 48.39 | 48.39 |
| | | Filler-8 | 30.27 | 30.27 | 30.27 | 30.27 | 30.27 | 30.27 | 30.27 |
| | (H) | TA 1 | 0.08 | 0.08 | 0.08 | 0.08 | 0.08 | 0.08 | 0.08 |
| | | TA 2 | 2.13 | 2.13 | 2.13 | 2.13 | 2.13 | 2.13 | 2.13 |
| | (I) | Pigment | 0.05 | 0.05 | 0.05 | 0.05 | 0.05 | 0.05 | 0.05 |
| | (G) | Inhibitor | 0.01 | 0.01 | 0 | 0.01 | 0.01 | 0.01 | 0 |
| | (D) | Additive-1 | 0.2 | 0.4 | 0.2 | 0 | 0 | 0 | 0 |
| | | Additive-2 | 0 | 0 | 0 | 0.2 | 0 | 0 | 0 |
| | | Additive-3 | 0 | 0 | 0 | 0 | 0.2 | 0 | 0 |
| | (E) | XL 1 | 0.39 | 0.39 | 0 | 0.39 | 0.39 | 0.39 | 0 |
| | (F) | Pt 1 | 0.02 | 0.02 | 0 | 0.02 | 0.02 | 0.02 | 0 |

| Thermal conductivity | | 9.2 | 9.2 | 9.2 | 9.2 | 9.2 | 9.2 | 9.3 |
|---|---|---|---|---|---|---|---|---|
| (W/m · K) | | | | | | | | |
| Dispensing rate | | 25.8 | 24.4 | 18.5 | 25.3 | 21.1 | 24.1 | 18.7 |
| (g/min.) | | | | | | | | |
| Long tailing | | No tail | No tail | No tail | No tail | No tail | No tail | No tail |
| observation | | | | | | | | |
| Anti-slumping | | No | No | No | No | No | Slumping | Slumping |
| | | slumping | slumping | slumping | slumping | slumping | | |
| Vertical holding | | No drop | No drop | No drop | No drop | No drop | Drop | Drop |
| Viscosity | at 0.1 (1/s) | 7942 | 7602 | 8696 | 7325 | 8212 | 4756 | 4890 |
| (Pa · s) | at 1 (1/s) | 1545 | 1699 | 1731 | 1677 | 2031 | 1622 | 1678 |

| | | | | | | | |
|---|---|---|---|---|---|---|---|
| Thixotropic index | 5.14 | 4.47 | 5.02 | 4.37 | 4.04 | 2.93 | 2.91 |

It was confirmed from the results of Examples IE1 to IE5 that in the followings:
The total fillers (AlN, BN, Al₂O₃, SiO₂ and ZnO) loading is 95.83 wt. %, so that these samples exhibit a thermal conductivity of 9.2 W/m·K. However, these samples exhibit excellent anti-slumping and vertical holding.

It was confirmed from the results of Comparative Examples CE1 and CE2 that in the followings:
The total fillers (AlN, BN, Al₂O₃, SiO₂ and ZnO) loading is 95.83 mass %, so that these samples exhibit a thermal conductivity of 9.2 W/m·K, or 9.3 W/m·K. However, these samples exhibit poor anti-slumping and poor vertical holding.

### Example IE6 and Comparative Examples CE3 and CE4

The thermally conductive silicone compositions shown in Table 2 were prepared using 4 L Sigma-blade kneader mixer.

Load the specified amount of V-P1, V-P2, TA 1, TA 2 and Pigment into the mixer and mix for 5 minutes at 20 revolutions per minute (RPM) under nitrogen flow at 0.4 cubic meters per hour. Add Filler-1 and Filler-5 while mixing and continue mixing for 10 minutes at 45 RPM under nitrogen purge. Add Filler-4 and mix for 10 minutes at 45 RPM under nitrogen purge. Stop mixing and scrape material down from the walls of the mixing container and cover. Add Filler-3 and mix for 10 minutes at 30 RPM under nitrogen purge. Add the Filler-2 and mix for 10 minutes at 30 RPM under nitrogen purge Stop mixing and scrape material down from the walls of the mixing container. Continue mixing at 30 RPM under vacuum and heat to 130° C. for 40 minutes. Cool to 40° C., stop mixing and release vacuum. Scrape material down from the container wall and mixer blade. Add inhibitor, XL 1 and Additive-1, and mix for 15 minutes at 30 RPM under nitrogen purge then for 15 minutes. Cool to 25° C., adding Pt 1 into mixer, mix for 45 mins at 30 RPM under nitrogen purge. Continue mixing for 20 mins at 30 RPM with full vacuum. Stop mixing and release the vacuum to obtain the thermally conductive silicone compositions for CE or IE.

TABLE 2

| | | | Category | | |
|---|---|---|---|---|---|
| | | | Example | Comparative Examples | |
| Item | | | IE 6 | CE 3 | CE 4 |
| Thermally | (A) | V-P1 | 1.68 | 1.88 | 1.88 |
| Conductive | | V-P2 | 0.13 | 0.13 | 0.13 |
| silicone | (B) | Filler-1 | 0.05 | 0.05 | 0.80 |
| composition | (C) | Filler-2 | 30.45 | 30.45 | 30.45 |
| (parts by | | Filler-3 | 29.22 | 29.22 | 29.22 |
| mass) | | Filler-4 | 23.26 | 23.26 | 23.26 |
| | | Filler-5 | 12.94 | 12.94 | 12.19 |
| | | Filler-6 | 0 | 0 | 0 |
| | | Filler-7 | 0 | 0 | 0 |
| | | Filler-8 | 0 | 0 | 0 |
| | (H) | TA 1 | 0.10 | 0.10 | 0.10 |
| | | TA 2 | 1.52 | 1.52 | 1.52 |
| | (I) | Pigment | 0.12 | 0.12 | 0.12 |
| | (G) | Inhibitor | 0.03 | 0.03 | 0.03 |
| | (D) | Additive-1 | 0.2 | 0 | 0 |
| | | Additive-2 | 0 | 0 | 0 |
| | | Additive-3 | 0 | 0 | 0 |
| | (E) | XL 1 | 0.27 | 0.27 | 0.27 |
| | (F) | Pt 1 | 0.03 | 0.03 | 0.03 |

| Thermal conductivity (W/m · K) | | 6.2 | 6.2 | 6.0 |
|---|---|---|---|---|
| Dispensing rate (g/min.) | | 19.8 | 17.8 | 13.1 |
| Long tailing observation | | No tail | No tail | Long tail |
| Anti-slumping | | No slumping | Slumping | Slumping |
| Vertical holding | | No drop | Drop | No drop |
| Viscosity | at 0.1 (1/s) | 8731 | 4436 | 14000 |
| (Pa · s) | at 1 (1/s) | 1763 | 1720 | 2760 |

| | | | |
|---|---|---|---|
| Thixotropic index | 4.95 | 2.58 | 5.07 |

It was confirmed from the results of Example IE6 that in the followings:
The total fillers (Al₂O₃, SiO₂ and ZnO) loading is 95.92 mass %, so that this sample exhibits a thermal conductivity of 6.2 W/m·K. However, this sample exhibits excellent anti-slumping and vertical holding.

It was confirmed from the results of Comparative Example CE3 and CE4 that in the followings:
The total fillers (Al₂O₃, SiO₂ and ZnO) loading for CE3 is 95.92 mass %, so that this sample exhibits a thermal conductivity of 6.2 W/m·K. However, this sample exhibits poor anti-slumping and poor vertical holding.

While, the total fillers (Al₂O₃, SiO₂ and ZnO) loading for CE4 is also 95.92 ass %, so that this sample exhibits a thermal conductivity of 6.0 W/m·K. However, the tip of the dots still easy to collapse, but it can maintain at original place during vertical holding test. Due to higher loading of nano SiO₂, the viscosity is also increased a lot. The long tailing performance and lower dispensability cannot meet the requirement.

### INDUSTRIAL APPLICABILITY

Because the thermally conductive curable silicone composition of the present invention exhibits good shape-holding property and high thermal conductivity despite good handleability and dispensability, the composition is useful as encapsulants or potting materials in electric/electronic devices.

1. A thermally conductive silicone composition comprising:
(A) an organopolysiloxane having at least one alkenyl group with 2 to 12 carbon atoms per molecule and having a viscosity at 25° C. of from 10 to 10,000 mPa·s;
(B) a hydrophobic fumed silica;
(C) at least one thermally conductive filler; and
(D) at least one polyether selected from a group consisting of (D₁) a polytetramethylene ether glycol, (D₂) an alcohol initiated ethylene oxide and propylene oxide copolymer, and (D₃) a polyether-modified organopolysiloxane;
wherein a content of component (A) is in a range of from 0.5 to 5 mass %, a content of component (B) is in a range of from 0.01 to 0.5 mass %, a content of component (C) is at least 90 mass %, and a content of component (D) is in a range of from 0.05 to 5 mass %, each relative to a total amount of the composition.

2. The thermally conductive silicone composition according to claim 1, wherein component (D₁) is present and is a polytetramethylene ether glycol represented by the following general formula: 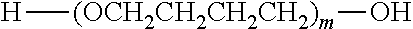
wherein m is an adequate number to give the polytetramethylene ether glycol a molecular weight a number average molecular weight (Mn) as measured by the gel permeation chromatography method of from 300 to 3,000.

3. The thermally conductive silicone composition according to claim 1, wherein component (D₂) is present and is an alcohol initiated ethylene oxide and propylene oxide copolymer comprises from 50 mass % to 99 mass % of propylene oxide units in the copolymer.

4. The thermally conductive silicone composition according to claim 1, wherein component (D₃) is present and is a polyether-modified organopolysiloxane selected from a polyether-grafted organopolysiloxane or a block copolymer of a polyether and an organopolysiloxane.

5. The thermally conductive silicone composition according to claim 1, further comprises:
(E) an organopolysiloxane having at least two silicon bonded hydrogen atoms per molecule in an amount such that silicon atom-bonded hydrogen atoms in component (E) are 0.1 to 5 mol per 1 mol of the alkenyl groups in component (A); and
(F) a hydrosilylation reaction catalyst in a sufficient amount to promote curing of the present composition.

6. The thermally conductive silicone composition according to claim 5, further comprises:
(G) a hydrosilylation reaction inhibitor, in an amount sufficient to control cure speed of the composition.

7. The thermally conductive silicone composition according to claim 1, further comprises:
(H) a filler treating agent, in an amount sufficient to treat component (C).

8. The thermally conductive silicone composition according to claim 1, further comprises:
(I) a pigment, in an amount sufficient to preserve desired physical properties to the composition.

9. The thermally conductive silicone composition according to claim 6, further comprises:
(H) a filler treating agent, in an amount sufficient to treat component (C).

10. The thermally conductive silicone composition according to claim 9, further comprises:
(I) a pigment, in an amount sufficient to preserve desired physical properties to the composition.
